(19) United States
(12) Patent Application Publication
(10) Pub. No.: US 2025/0309107 A1
(43) Pub. Date: Oct. 2, 2025

(54) SEMICONDUCTOR DEVICE AND METHOD OF MANUFACTURING THE SAME

(71) Applicant: Renesas Electronics Corporation, Tokyo (JP)

(72) Inventor: Nobuhito SHIRAISHI, Tokyo (JP)

(21) Appl. No.: 18/971,163

(22) Filed: Dec. 6, 2024

(30) Foreign Application Priority Data
Mar. 29, 2024 (JP) 2024-056150

(51) Int. Cl. H01L 23/522; H01L 21/768; H01L 23/528; H01L 23/532

(52) U.S. Cl. CPC H01L 23/5228; H01L 21/76892; H01L 23/5283; H01L 23/53261

(57) ABSTRACT

A semiconductor device includes a semiconductor substrate, a first interlayer dielectric film formed over the semiconductor substrate, a first wiring formed on the first interlayer dielectric film, a second interlayer dielectric film formed on the first interlayer dielectric film and including a first layer covering the first wiring and a second layer formed on the first layer, a first resistive film formed on the first layer and covered by the second layer, a first via plug formed in the first layer and electrically connecting the first wiring and the first resistive film, and a second via plug formed in the second interlayer dielectric film and electrically connected to the first wiring. The first resistive film contains silicon.

### CROSS-REFERENCE TO RELATED APPLICATIONS

The disclosure of Japanese Patent Application No. 2024-056150 filed on Mar. 29, 2024, including the specification, drawings and abstract is incorporated herein by reference in its entirety.

### BACKGROUND

This disclosure relates to semiconductor devices and methods for manufacturing semiconductor devices.

There are disclosed techniques listed below.

[Patent Document 1] Japanese Unexamined Patent Application Publication No. 2023-160003

A semiconductor device according to Patent Document 1, includes a semiconductor substrate, a first interlayer dielectric film, a wiring, a second interlayer dielectric film, a via plug, and a resistive film. The first interlayer dielectric film is formed over the semiconductor substrate. The second interlayer dielectric film includes a first layer and a second layer. The first layer of the second interlayer dielectric film is formed on the first interlayer dielectric film to cover the wiring. A via hole is formed in the first layer of the second interlayer dielectric film. The resistive film is formed on the first layer of the second interlayer dielectric film. The via plug is formed in the via hole and electrically connects the wiring and the resistive film. The second layer of the second interlayer dielectric film is formed on the first layer of the second interlayer dielectric film to cover the resistive film. The resistive film contains silicon.

### SUMMARY

In the semiconductor device described in Patent Document 1, after the resistive film is formed and before the second layer of the second interlayer dielectric film is formed, washing may be performed. At this time, the silicon in the resistive film may dissolve, causing the width of the resistive film to decrease and the electrical resistance value of the resistive film to fluctuate. Other problems and novel features will become apparent from the description and the accompanying drawings of this specification.

The semiconductor device of this disclosure includes a semiconductor substrate, a first interlayer dielectric film formed over the semiconductor substrate, a first wiring formed on the first interlayer dielectric film, a second interlayer dielectric film formed on the first interlayer dielectric film and having a first layer covering the first wiring and a second layer formed on the first layer, a first resistive film formed on the first layer and covered by the second layer, a first via plug formed in the first layer and electrically connecting the first wiring and the first resistive film, and a second via plug formed in the second interlayer dielectric film and electrically connected to the first wiring. The first resistive film contains silicon. The first resistive film is electrically connected to the semiconductor substrate via the first wiring, the first via plug, and the second via plug.

The method of manufacturing a semiconductor device of this disclosure includes: forming a first interlayer dielectric film over a semiconductor substrate, forming a first wiring on the first interlayer dielectric film, forming a first layer of a second interlayer dielectric film on the first interlayer dielectric film to cover the first wiring, forming a first via plug in the first layer to be electrically connected to the first wiring, forming a first resistive film containing silicon on the first layer to be electrically connected to the first via plug, forming a second layer of the second interlayer dielectric film on the first layer to cover the first resistive film, and after forming the first resistive film, cleaning the upper surface of the first layer. In cleaning the upper surface of the first layer, the upper surface of the first layer is cleaned in a state where the first resistive film is not electrically connected to the semiconductor substrate.

According to this disclosure, the reliability of semiconductor devices can be improved.

### BRIEF DESCRIPTION OF THE DRAWINGS

FIG. 1 is a cross-sectional view of a semiconductor device DEV1.

FIG. 2 is a manufacturing step diagram of the semiconductor device DEV1.

FIG. 3 is a cross-sectional view for explaining the interlayer dielectric film formation step S2.

FIG. 4 is a cross-sectional view for explaining the contact plug formation step S3.

FIG. 5 is a cross-sectional view for explaining the wiring layer formation step S4.

FIG. 6 is a cross-sectional view for explaining the interlayer dielectric film formation step S5.

FIG. 7 is a cross-sectional view for explaining the via plug formation step S6.

FIG. 8 is a cross-sectional view for explaining the wiring layer formation step S7.

FIG. 9 is a cross-sectional view for explaining the interlayer dielectric film formation step S8.

FIG. 10 is a cross-sectional view for explaining the via plug formation step S9.

FIG. 11 is a cross-sectional view for explaining the resistive film formation step S10.

FIG. 12 is a cross-sectional view for explaining the interlayer dielectric film formation step S12.

FIG. 13 is a cross-sectional view for explaining the via plug formation step S13.

FIG. 14 is a cross-sectional view of the semiconductor device DEV1 according to a modified example.

FIG. 15 is a first cross-sectional view of a semiconductor device DEV2.

FIG. 16 is a second cross-sectional view of the semiconductor device DEV2.

FIG. 17 is a cross-sectional view for explaining the resistive film formation step S10 in the manufacturing method of the semiconductor device DEV2.

### DETAILED DESCRIPTION

The details of embodiments of the present disclosure are described with reference to the drawings. In the following drawings, the same or corresponding parts are designated with the same reference numerals, and redundant descriptions are not repeated.

### First Embodiment

A semiconductor device DEV1 according to the first embodiment is described.

### Structure of Semiconductor Device DEV1

The configuration of the semiconductor device DEV1 is described below.

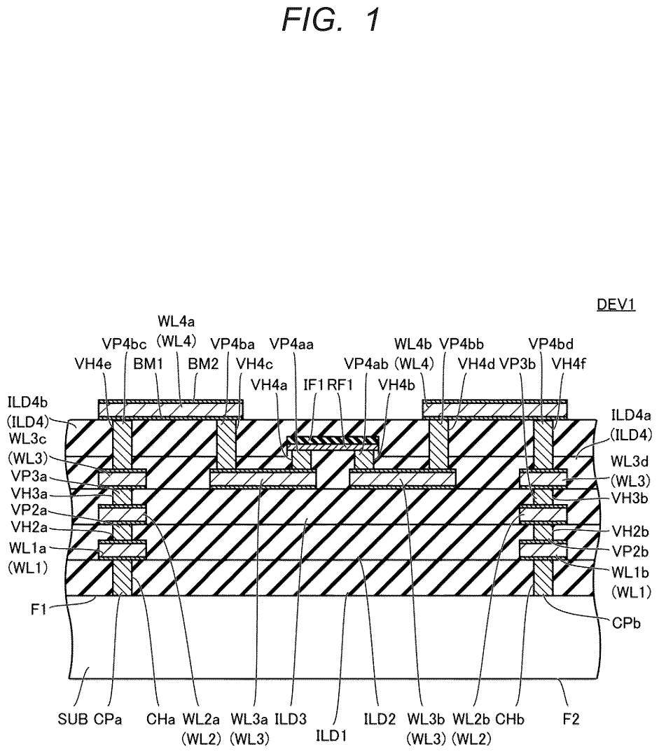

As shown in FIG. 1, the semiconductor device DEV1 includes a semiconductor substrate SUB. The semiconductor substrate SUB has an upper surface F1 and a lower surface F2. The lower surface F2 is located on the opposite side of the upper surface F1. The semiconductor substrate SUB is formed, for example, of single crystal silicon.

Although not shown, in the semiconductor substrate SUB, a source region, a drain region, and a well region are formed. The source region and the drain region are formed at the upper surface F1. The source region and the drain region are separated from each other. The well region is formed at the upper surface F1 to surround the source region and the drain region. A portion of the well region located between the source region and the drain region is the channel region. Although not shown, a gate dielectric film is formed on the channel region, and a gate electrode is formed on the gate dielectric film. The source regions, the drain regions, the well region, the gate dielectric film, and the gate electrode configure a transistor.

Furthermore, the semiconductor device DEV1 includes an interlayer dielectric film ILD1, an interlayer dielectric film ILD2, an interlayer dielectric film ILD3, an interlayer dielectric film ILD4, a wiring layer WL1, a wiring layer WL2, a wiring layer WL3, and a wiring layer WL4.

The interlayer dielectric film ILD1 is formed on the semiconductor substrate SUB (upper surface F1) to cover the aforementioned transistor. The wiring layer WL1 is formed on the interlayer dielectric film ILD1. The interlayer dielectric film ILD2 is formed on the interlayer dielectric film ILD1 to cover the wiring layer WL1. The wiring layer WL2 is formed on the interlayer dielectric film ILD2. The interlayer dielectric film ILD3 is formed on the interlayer dielectric film ILD2 to cover the wiring layer WL2. The wiring layer WL3 is formed on the interlayer dielectric film ILD3. The interlayer dielectric film ILD4 is formed on the interlayer dielectric film ILD3 to cover the wiring layer WL3. The wiring layer WL4 is formed on the interlayer dielectric film ILD4.

The interlayer dielectric film ILD1 to the interlayer dielectric film ILD4 are, for example, formed of silicon oxide. The wiring layer WL1 to the wiring layer WL4 are, for example, formed of aluminum or an aluminum alloy. Each of the wiring layer WL1 to the wiring layer WL4 may be formed on a barrier metal BM1. Furthermore, a barrier metal BM2 may be formed on the upper surface of each of the wiring layer WL1 to the wiring layer WL4. The barrier metal BM1 and the barrier metal BM2 are, for example, a laminated film of a titanium nitride film and a titanium film.

As shown in FIG. 1, the semiconductor device DEV1 further includes a resistive film RF1. The wiring layer WL3 includes a wiring WL3a and a wiring WL3b. The interlayer dielectric film ILD4 includes a first layer ILD4a and a second layer ILD4b. The first layer ILD4a is formed on the interlayer dielectric film ILD3 to cover the wiring layer WL3.

The resistive film RF1 is formed on the first layer ILD4a. A dielectric film IF1 is formed on the resistive film RF1. The side surface of the resistive film RF1 is exposed from between the dielectric film IF1 and the first layer ILD4a. The second layer ILD4b is formed on the first layer ILD4a to cover the resistive film RF1 and the dielectric film IF1. The resistive film RF1 contains silicon. The resistive film RF1 is formed of, for example, Sier or SiCrC. The dielectric film IF1 is formed of, for example, silicon oxide or silicon oxynitride.

In the first layer ILD4a, a via hole VH4a and a via hole VH4b are formed. The via hole VH4a and the via hole VH4b VH 4b are penetrate through the first layer ILD4a. In plan view, the via hole VH4a overlaps the resistive film RF1 and the wiring WL3a. In plan view, the via hole VH4b overlaps the resistive film RF1 and the wiring WL3b.

The semiconductor device DEV1 further includes a via plug VP4aa and a via plug VP4ab. It should be noted that the via plug VP4aa and the via plug VP4ab may collectively be referred to as a via plug VP4a. The via plug VP4aa is formed in the via hole VH4a. The via plug VP4ab is formed in the via hole VH4b. The via plug VP4aa electrically connects the resistive film RF1 and the wiring WL3a. The via plug VP4ab electrically connects the resistive film RF1 and the wiring WL3b. The via plug VP4a is formed of, for example, tungsten.

The wiring layer WL3 further includes a wiring WL3c and a wiring WL3d, and the wiring layer WL4 includes a wiring WL4a and a wiring WL4b. In the interlayer dielectric film ILD4, a via hole VH4c, a via hole VH4d, a via hole VH4e, and a via hole VH4f are formed. The via hole VH4c, the via hole VH4d, the via hole VH4e, and the via hole VH4f penetrate through the interlayer dielectric film ILD4. In plan view, the via hole VH4c overlaps the wiring WL4a and the wiring WL3a, and the via hole VH4d overlaps the wiring WL4b and the wiring WL3b. In plan view, the via hole VH4e overlaps the wiring WL4a and the wiring WL3c, and the via hole VH4f overlaps the wiring WL4b and the wiring WL3d.

The semiconductor device DEV1 further includes a via plug VP4ba, a via plug VP4bb, the via plug VP4bc, and the via plug VP4bd. It should be noted that the via plug VP4ba, the via plug VP4bb, the via plug VP4bc, and the via plug VP4bd may collectively be referred to as a via plug VP4b. The via plug VP4ba is formed in the via hole VH4c. The via plug VP4bb is formed in the via hole VH4d. The via plug VP4bc is formed in the via hole VH4e. The via plug VP4bd is formed in the via hole VH4f. The via plug VP4ba electrically connects the wiring WL4a and the wiring WL3a. The via plug VP4bb electrically connects the wiring WL4b and the wiring WL3b. The via plug VP4bc electrically connects the wiring WL4a and the wiring WL3c. The via plug VP4bd electrically connects the wiring WL4b and the wiring WL3d. The via plug VP4b is formed of, for example, tungsten.

The wiring layer WL2 includes a wiring WL2a and a wiring WL2b, and the wiring layer WL1 includes a wiring WL1a and a wiring WL1b. The semiconductor device DEV1 further includes a via plug VP3a, a via plug VP3b, a via plug VP2a, a via plug VP2b, a contact plug CPa and a contact plug CPb. It should be noted that the via plug VP3a and the via plug VP3b may collectively be referred to as a via plug VP3, and the via plug VP2a and the via plug VP2b may collectively be referred to as a via plug VP2. Furthermore, the contact plug CPa and the contact plug CPb may collectively be referred to as a contact plug CP.

A via hole VH3a is formed in the interlayer dielectric film ILD3 to overlap the wiring WL3c and the wiring WL2a in plan view, and a via hole VH3b is formed to overlap the wiring WL3d and the wiring WL2b in plan view. The via hole VH3a and the via hole VH3b penetrate through the interlayer dielectric film ILD3. In the interlayer dielectric film ILD2, a via hole VH2a is formed to overlap the wiring WL2a and the wiring WL1a in plan view, and a via hole VH2b is formed to overlap the wiring WL2b and the the wiring WL1b in plan view. The via hole VH2a and the via hole VH2b penetrate through the interlayer dielectric film ILD2.

In the interlayer dielectric film ILD1, a contact hole CHa is formed to overlap the wiring WL1a in plan view, and a contact hole CHb is formed to overlap the wiring WL1b in plan view. The contact hole CHa and the contact hole CHb penetrate through the interlayer dielectric film ILD1.

The via plug VP3a is formed in the via hole VH3a. The via plug VP3b is formed in the via hole VH3b. The via plug VP3a electrically connects the wiring WL3c and the wiring WL2a. The via plug VP3b electrically connects the wiring WL3d and the wiring WL2b. The via plug VP2a is formed in the via hole VH2a. The via plug VP2b is formed in the via hole VH2b. The via plug VP2a electrically connects the wiring WL2a and the wiring WL1a. The via plug VP2b electrically connects the wiring WL2b and the wiring WL1b. The contact plug CPa is formed in the contact hole CHa. The contact plug CPb is formed in the contact hole CHb. The contact plug CPa electrically connects the wiring WL1a and the semiconductor substrate (source or drain region of a transistor) and the contact plug CPb electrically connects the the wiring WL1b and the semiconductor substrate SUB. The via plug VP3, the via plug VP2, and the contact plug CP are formed of, for example, tungsten.

Thus, the resistive film RF1 is electrically connected to the semiconductor substrate SUB via the wiring WL3, the via plug VP4aa, and the via plug VP4ba. Further, the resistive film RF1 is electrically connected to the semiconductor substrate SUB via the wiring WL3b, the via plug VP4ab, and the via plug VP4bb. As shown in FIG. 1, the resistive film RF1 is electrically connected to the semiconductor substrate SUB via the wiring WL4a and is also electrically connected to the semiconductor substrate SUB via the wiring WL4b, however, the resistive film RF1 may be electrically connected to a different structure than the semiconductor substrate SUB via the wiring WL4b while being connected to the semiconductor substrate SUB via the wiring WL4a.

### Manufacturing Method of Semiconductor Device DEV1

Hereinafter, the manufacturing method of the semiconductor device DEV1 is described.

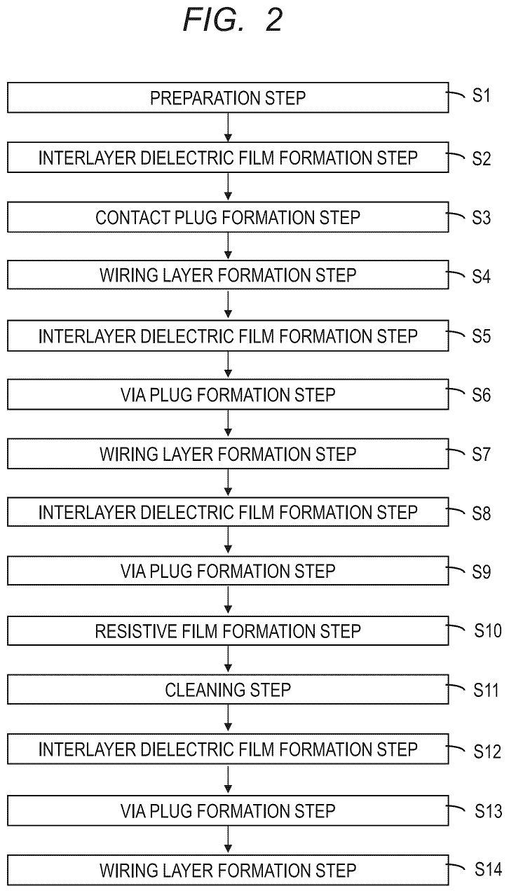

As shown in FIG. 2, the manufacturing method of the semiconductor device DEV1 includes a preparation step S1, an interlayer dielectric film formation step S2, a contact plug formation step S3, a wiring layer formation step S4, an interlayer dielectric film formation step S5, and a via plug formation step S6.

In the preparation step S1, the semiconductor substrate SUB is prepared. In the semiconductor substrate SUB prepared in preparation step S1, the source region, the drain region, and the well region are formed, and on the semiconductor substrate SUB, the gate dielectric film, and the gate electrode are formed.

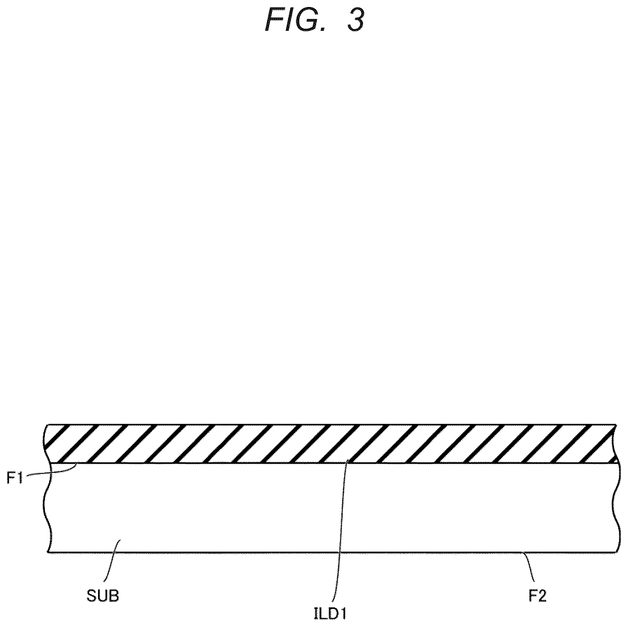

As shown in FIG. 3, in the interlayer dielectric film formation step S2, the interlayer dielectric film ILD1 is formed on the semiconductor substrate SUB. The interlayer dielectric film ILD1 is formed by, for example, depositing the constituent material of the interlayer dielectric film ILD1 on the semiconductor substrate SUB by a Chemical Vapor Deposition (CVD) method, and then planarizing the deposited constituent material of the interlayer dielectric film ILD1 by, for example, a Chemical Mechanical Polishing (CMP) method.

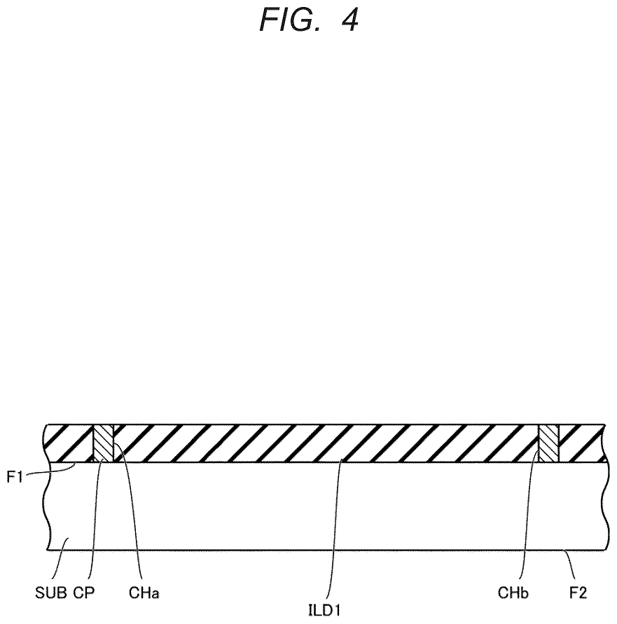

As shown in FIG. 4, in the contact plug formation step S3, after the contact hole CHa and the contact hole CHb are formed in the interlayer dielectric film ILD1, the contact plugs CP are formed in the contact hole CHa and the contact hole CHb. In the contact plug formation step S3, firstly, a resist pattern is formed on the interlayer dielectric film ILD1 by photolithography. Secondly, etching of the interlayer dielectric film ILD1 is performed using the resist pattern as a mask, thereby forming the contact hole CHa and the contact hole CHb. Thirdly, the contact plugs CP are formed in the contact hole CHa and the contact hole CHb, for example, by a CVD method. Fourthly, the material of the contact plugs CP formed outside the contact hole CHa and the contact hole CHb is removed, for example, by a CMP method.

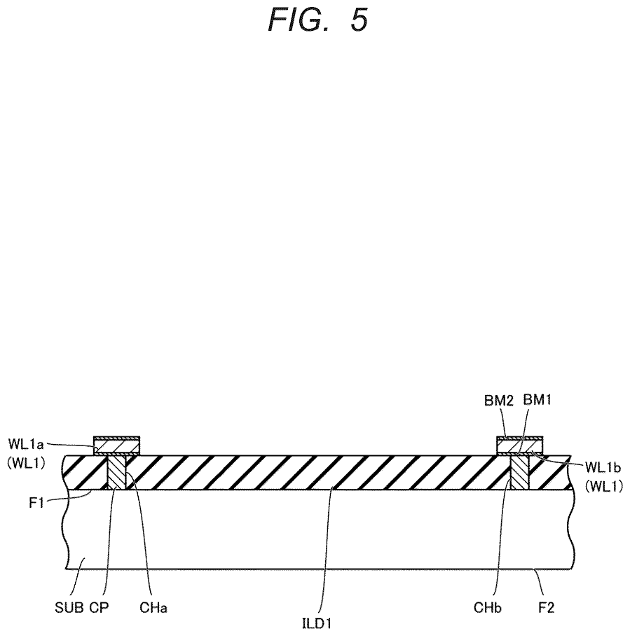

As shown in FIG. 5, in the wiring layer formation step S4, the wiring layer WL1 is formed on the interlayer dielectric film ILD1. In the wiring layer formation step S4, firstly, the materials for the barrier metal BM1, the wiring layer WL1, and the barrier metal BM2 are sequentially deposited, for example, by sputtering. Secondly, a resist pattern is formed on the deposited material of the barrier metal BM2 by photolithography. Thirdly, etching is performed on the materials for the barrier metal BM1, the wiring layer WL1, and the barrier metal BM2, using the resist pattern as a mask.

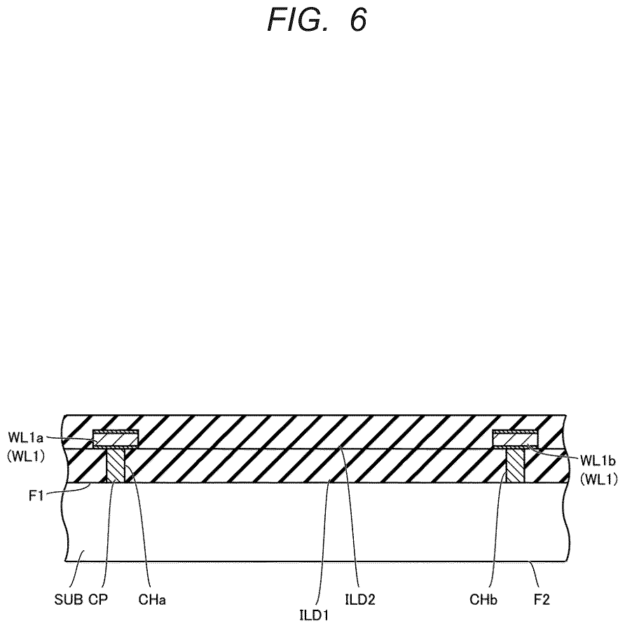

As shown in FIG. 6, in the interlayer dielectric film formation step S5, the interlayer dielectric film ILD2 is formed to cover the wiring layer WL1 on the interlayer dielectric film ILD1. In the interlayer dielectric film formation step S5, firstly, the constituent material of the interlayer dielectric film ILD2 is formed on the interlayer dielectric film ILD1 by, for example, a CVD method. Secondly, the constituent material of the deposited interlayer dielectric film ILD2 is planarized by, for example, a CMP method.

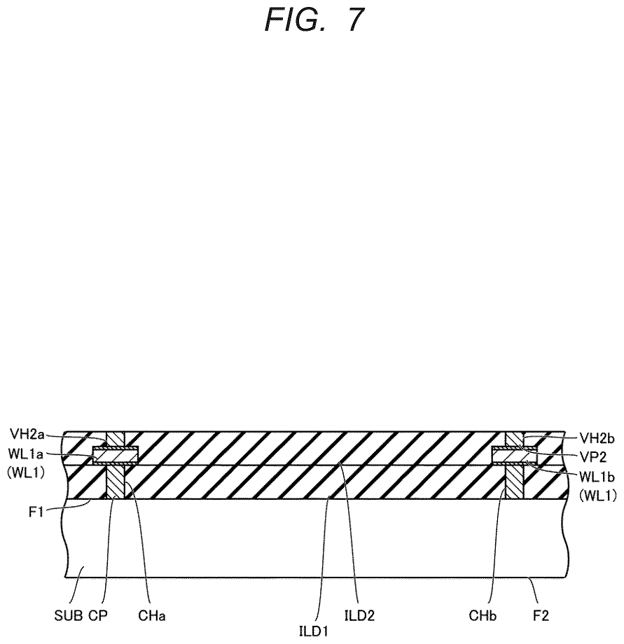

As shown in FIG. 7, in the via plug formation step S6, after the via hole VH2a and the via hole VH2b are formed in the interlayer dielectric film ILD2, the via plugs VP2 are formed in the via hole VH2a and the via hole VH2b. In the via plug formation step S6, firstly, a resist pattern is formed on the interlayer dielectric film ILD2 by photolithography. Secondly, etching of the interlayer dielectric film ILD2 is performed using the resist pattern as a mask, thereby forming the via hole VH2a and the via hole VH2b. Thirdly, the via plugs VP2 are formed in the via hole VH2a and the via hole VH2b, for example, by a CVD method. Fourthly, the material of the via plugs VP2 formed outside the via hole VH2a and the via hole VH2b is removed, for example, by a CMP method.

Subsequently, by repeating the step similar to the wiring layer formation step S4, the interlayer dielectric film formation step S5, and the via plug formation step S6, the wiring layer WL2, the interlayer dielectric film ILD3, the via hole VH3a, the via hole VH3b, and the via plugs VP3 are formed.

As shown in FIG. 2, the manufacturing method of the semiconductor device DEV1 further includes a wiring layer formation step S7, an interlayer dielectric film formation step S8, a via plug formation step S9, a resistive film formation step S10, a cleaning step S11, an interlayer dielectric film formation step S12, a via plug formation step S13, and a wiring layer formation step S14.

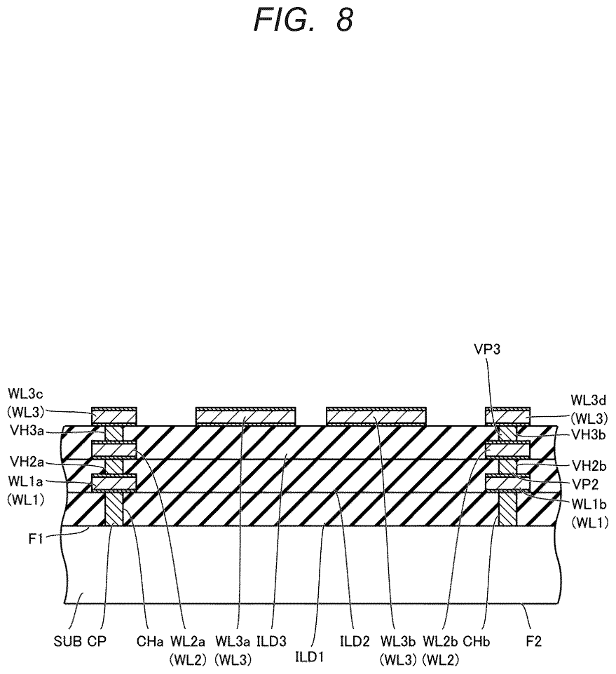

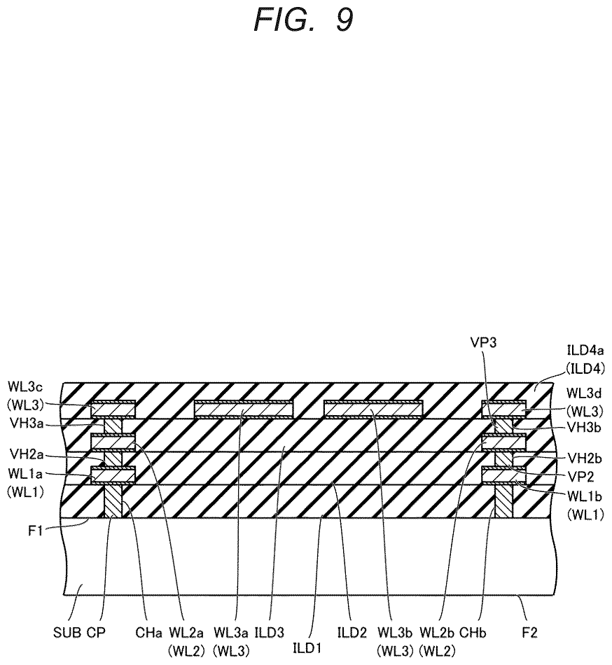

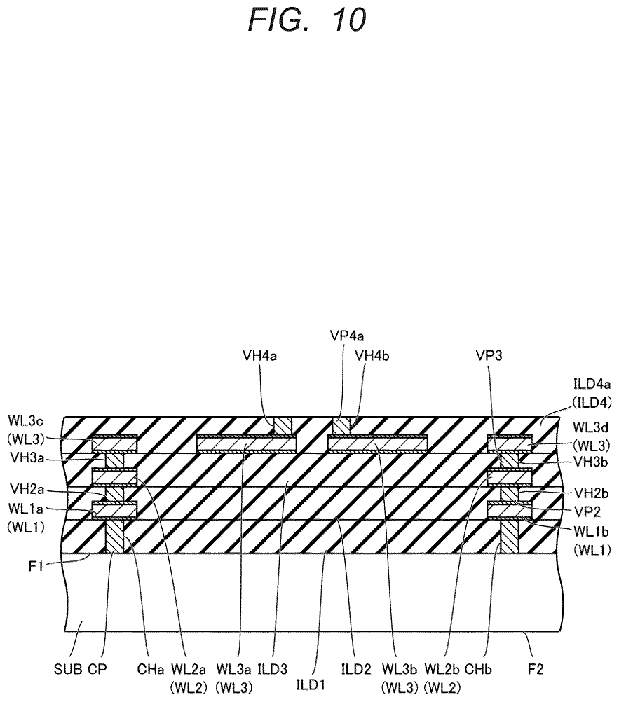

As shown in FIG. 8, in the wiring layer formation step S7, the wiring layer WL3 is formed on the interlayer dielectric film ILD3 in a similar manner to the wiring layer formation step S4. Specifically, the wiring WL3c and the wiring WL3d are formed to be electrically connected to the semiconductor substrate SUB, while the wiring WL3a and the wiring WL3b are formed not to be electrically connected to the semiconductor substrate SUB. As shown in FIG. 9, in the interlayer dielectric film formation step S8, the first layer ILD4a is formed on the interlayer dielectric film ILD3 to cover the wiring layer WL3, in a similar manner to the interlayer dielectric film formation step S5. As shown in FIG. 10, in the via plug formation step S9, after the via hole VH4a and the via hole VH4b are formed in the first layer ILD4a in a similar manner to the via plug formation step S6, the via plugs VP4a are formed in the via hole VH4a and the via hole VH4b.

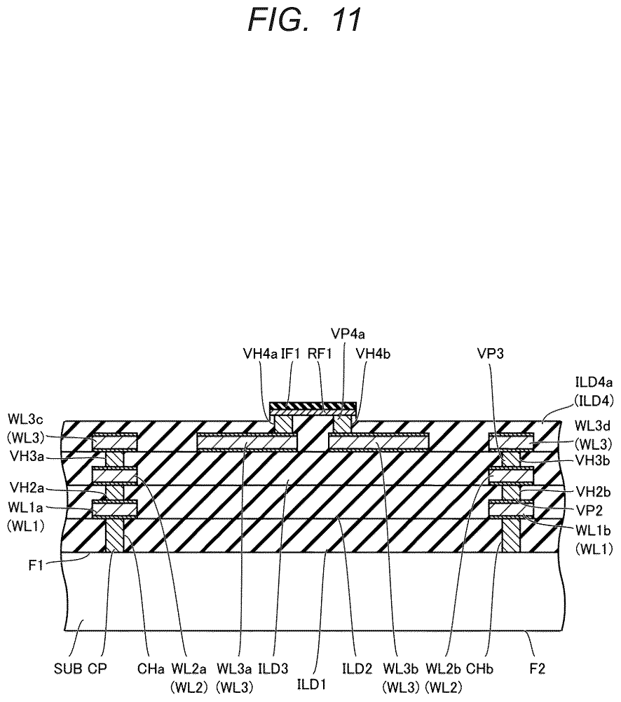

As shown in FIG. 11, in the resistive film formation step S10, the resistive film RF1 is formed on the first layer ILD4a. In the resistive film formation step S10, firstly, the constituent material of the resistive film RF1 and the constituent material of the dielectric film IF1 are sequentially deposited on the first layer ILD4a, for example, by CVD method. Secondly, a resist pattern is formed on the deposited constituent material of the dielectric film IF1 by photolithography. Thirdly, etching is performed on the deposited constituent material of the dielectric film IF1 using the resist pattern as a mask, thereby forming the dielectric film IF1. Thirdly, etching is performed on the deposited constituent material of the resistive film RF1 using the dielectric film IF1 as a mask, thereby forming the resistive film RF1. At this time, the resistive film RF1 is formed not to be electrically connected to the semiconductor substrate SUB.

In the cleaning step S11, cleaning is performed on a semiconductor wafer that has undergone the resist film formation step S10. Specifically, the upper surface of the first layer ILD4a is cleaned. In this cleaning, residues generated during etching in the resist film formation step S10 are removed using a solvent, and the solvent is removed by rinsing with water. In the cleaning step S11, the upper surface of the first layer ILD4a is cleaned while the resist film RF1 is not electrically connected to the semiconductor substrate SUB.

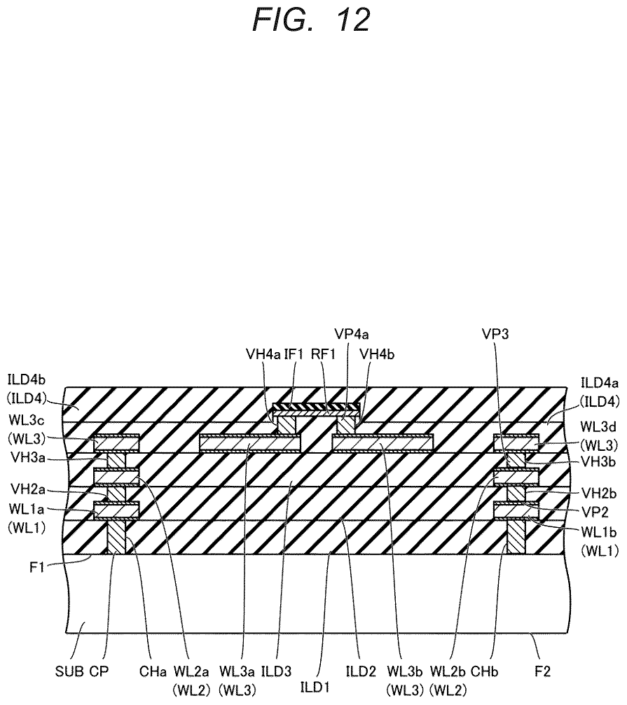

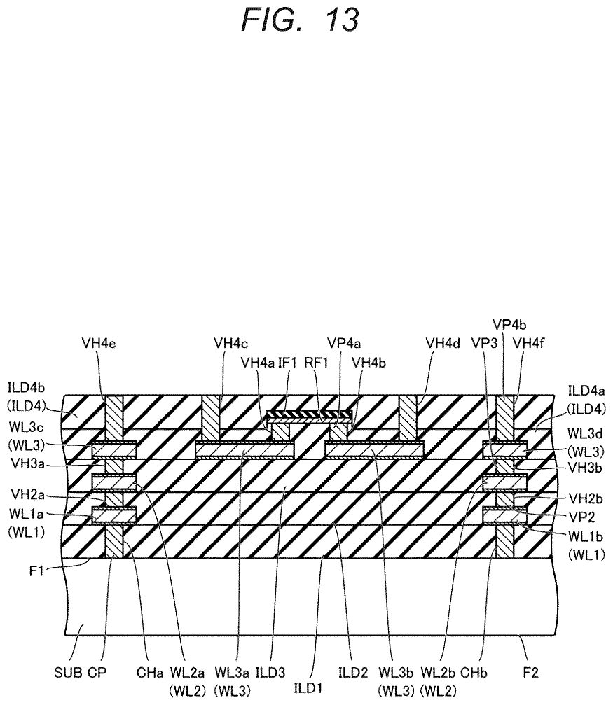

As shown in FIG. 12, in the interlayer dielectric film formation step S12, the second layer ILD4b is formed on the first layer ILD4a in a manner similar to the interlayer dielectric film formation step S5, to cover the resistive film RF1 and the dielectric film IF1. As shown in FIG. 13, in the via plug formation step S13, the via hole VH4c, the via hole VH4d, the via hole VH4e, and the via hole VH4f are formed in the interlayer dielectric film ILD4 in a manner similar to the via plug formation step S6, followed by the formation of the via plugs VP4b in the via hole VH4c, the via hole VH4d, the via hole VH4e, and the via hole VH4f. In the wiring layer formation step S14, the wiring layer WL4 is formed on the interlayer dielectric film ILD4 in a manner similar to the wiring layer formation step S4. By forming the wiring layer WL4, the resistive film RF1 and the semiconductor substrate SUB are electrically connected via the wiring layer WL4. Thus, the structure of the semiconductor device DEV1 shown in FIG. 1 is formed.

### Effects of Semiconductor Device DEV1

The effects of the semiconductor device DEV1 will be described below.

As described above, in the manufacturing step of the semiconductor device DEV1, rinsing is performed after the formation of the resistive film RF1 and before the formation of the second layer ILD4b. That is, in the manufacturing step of the semiconductor device DEV1, rinsing is performed while the side surfaces of the resistive film RF1 are exposed from the first layer ILD4a and the dielectric film IF1. At this time, because the resistive film RF1 becomes charged due to contact with water, if the resistive film RF1 is electrically connected to the semiconductor substrate SUB, current flows between the resistive film RF1 and the semiconductor substrate SUB, making the silicon contained in the resistive film RF1 more likely to dissolve. As a result, the width of the resistive film RF1 decreases, and the electrical resistance value of the resistive film RF1 fluctuates.

On the other hand, in the semiconductor device DEV1, the resistive film RF1 is electrically connected to the semiconductor substrate SUB via the via plug VP4, the wiring WL3a, and the via plug VP4ba, and also the via plug VP4ab, the wiring WL3b, and the via plug VP4ba. That is, the resistive film RF1 is not electrically connected to the semiconductor substrate SUB during rinsing. Therefore, in the semiconductor device DEV1, it is possible to suppress fluctuations in the electrical resistance value of the resistive film RF1 due to the dissolution of silicon in the resistive film RF1 caused by rinsing.

### Modified Example

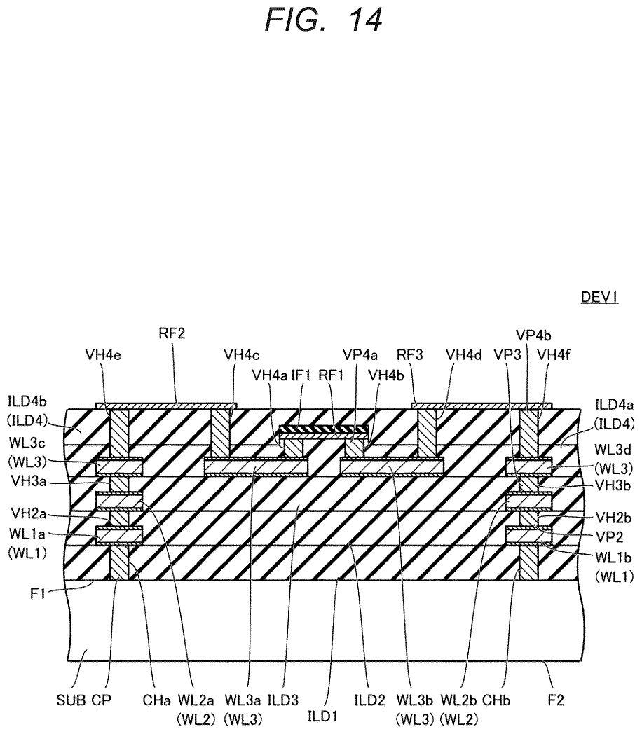

As shown in FIG. 14, in the semiconductor device DEV1, instead of the wiring WL4a and the wiring WL4b, a resistive film RF2 and a resistive film RF3 may be formed. That is, in the semiconductor device DEV1, if the resistive film RF1 is connected to the semiconductor substrate SUB via the via plug VP4, the wiring WL3a, and the via plug VP4ba, and if the resistive film RF1 is connected to the semiconductor substrate SUB via the via plug VP4ab, the wiring WL3b, and the via plug VP4bb, the method of connection between the via plug VP4ba and the semiconductor substrate SUB and the method of connection between the via plug VP4bb and the semiconductor substrate SUB are not particularly limited. The resistive film RF2 and the resistive film RF3 contain silicon. The resistive film RF2 and the resistive film RF3 are formed of, for example, SiCr or SiCrC.

### Second Embodiment

A semiconductor device DEV2 according to a second embodiment is described. Herein, primarily the differences from the semiconductor device DEV1 are described, and repetitive descriptions are not repeated.

### Structure of Semiconductor Device DEV2

Below, the structure of the semiconductor device DEV2 is described.

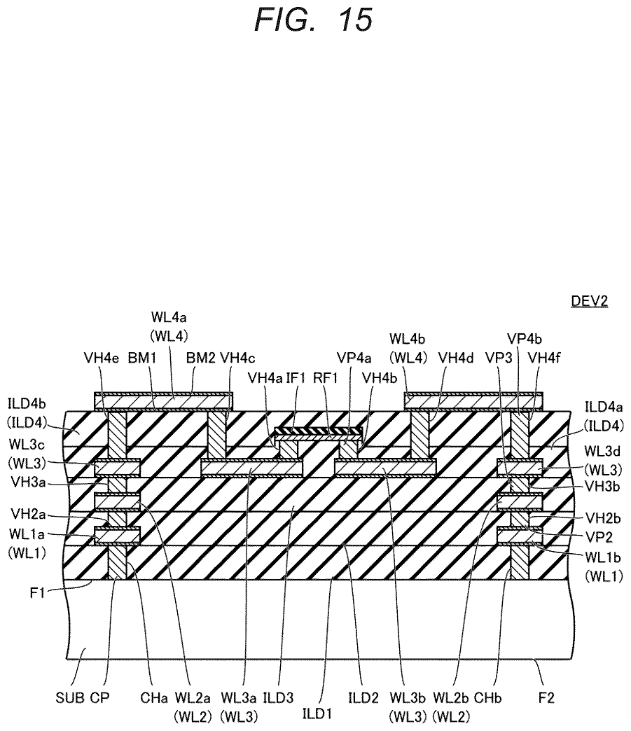

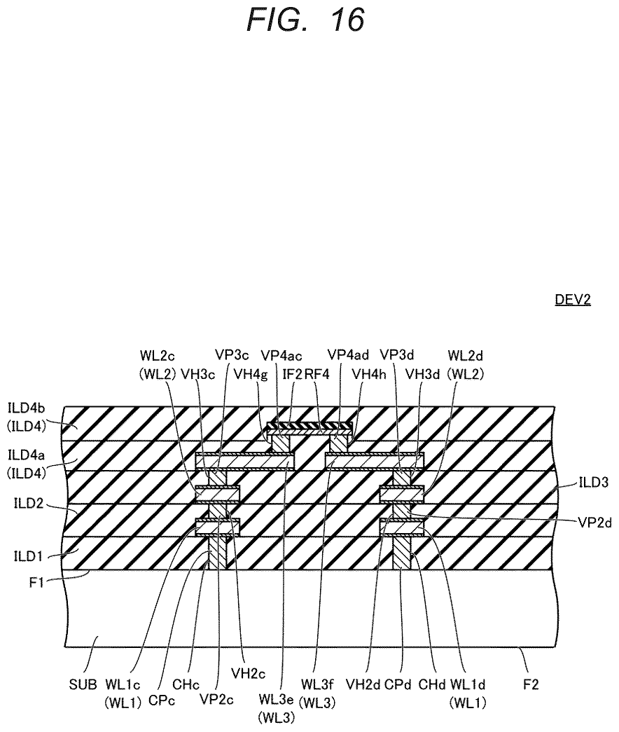

As shown in FIG. 15, the semiconductor device DEV2 includes the semiconductor substrate SUB, the interlayer dielectric film ILD1, the interlayer dielectric film ILD2, the interlayer dielectric film ILD3, the interlayer dielectric film ILD4, the wiring layer WL1, the wiring layer WL2, the wiring layer WL3, the wiring layer WL4, the resistive film RF1, and the dielectric film IF1. As shown in FIG. 16, the semiconductor device DEV2 further includes a resistive film RF4 and a dielectric film IF2. The resistive film RF4 contains silicon. For example, the resistive film RF4 is formed of SiCr or SiCrC. The dielectric film IF2 is formed of, for example, silicon oxide.

In the semiconductor device DEV2, a contact hole CHc and hole CHd are further formed in the interlayer a contact dielectric film ILD1. In the semiconductor device DEV2, a via hole VH2c and a via hole VH2d are further formed in the interlayer dielectric film ILD2. In the semiconductor device DEV2, a via hole VH3c and a via hole VH3d are further formed in the interlayer dielectric film ILD3. In the semiconductor device DEV2, a via hole VH4g and a via hole VH4h are further formed in the first layer ILD4a.

In the semiconductor device DEV2, the wiring layer WL1 further includes a wiring WLc and a wiring WL1d, and the wiring layer WL2 further includes a wiring WL2c and a wiring WL2d. In the semiconductor device DEV2, the wiring layer WL3 further includes a wiring WL3e and a wiring WL3f.

The contact hole CHc and the contact hole CHd overlap the wiring WL1c and the wiring WL1d, respectively, in plan view. A contact plug CPc is formed in the contact hole CHc and a contact plug CPd is formed in the contact hole CHd. The contact plug CPC electrically connects the wiring WL1c to the semiconductor substrate SUB, and the contact plug CPd electrically connects the wiring WL1d to the semiconductor substrate SUB.

The via hole VH2c overlaps the wiring WL1c and the wiring WL2c in plan view. The via hole VH2d overlaps the wiring WL1d and the wiring WL2d in plan view. A via plug VP2c is formed in the via hole VH2c, and a via plug VP2d is formed in the via hole VH2d. The via plug VP2c electrically connects the wiring WL1c and the wiring WL2c, and the via plug VP2d electrically connects the wiring WL1d and the wiring WL2d.

In plan view, the via hole VH3c overlaps the wiring WL2c and the wiring WL3e. In plan view, the via hole VH3d overlaps the wiring WL2d and the wiring WL3f. A via plug VP3c is formed in the via hole VH3c, and a via plug VP3d is formed in the via hole VH3d. The via plug VP3c electrically connects the wiring WL2c and the wiring WL3c, and the via plug VP3d electrically connects the wiring WL2d and the wiring WL3d.

In plan view, the via hole VH4g overlaps the resistive film RF4 and the wiring WL3e. In plan view, the via hole VH4h overlaps the resistive film RF4 and the wiring WL3f. A via plug VP4ac is formed in the via hole VH4g, and a via plug VP4ad is formed in the via hole VH4h. The via plug VP4ac electrically connects the wiring WL3e and the resistive film RF4, and the via plug VP4d electrically connects the wiring WL3f and the resistive film RF4. Therefore, the resistive film RF4 is electrically connected to the semiconductor substrate SUB via the wiring WL3e, the via plug VP4ac, and the via plug VP3c, as well as via the wiring WL3f, the via plug VP4ad, and the via plug VP3d.

The width of the resistive film RF4, for example, is smaller than the width of the resistive film RF1. The width of the resistive film RF1 is measured in a direction perpendicular to the direction in which the via plugs VP4a connected to the resistive film RF1 are aligned, in plan view. Also, the width of the resistive film RF4 is measured in a direction perpendicular to the direction in which the via plugs VP4a connected to the resistive film RF4 are aligned, in plan view. The electrical resistance value of the resistive film RF4, for example, is greater than the electrical resistance value of the resistive film RF1.

In the semiconductor device DEV2, for example, the resistive film RF1 is electrically connected to the transistor configuring the first circuit, and the resistive film RF4 is electrically connected to the transistor configuring the second circuit. The accuracy of the electrical resistance value required for the second circuit may be lower than the accuracy of the electrical resistance value required for the first circuit.

### Manufacturing Method of Semiconductor Device DEV2

The manufacturing method of the semiconductor device DEV2 includes the preparation step S1, the interlayer dielectric film formation step S2, the contact plug formation step S3, the wiring layer formation step S4, the interlayer dielectric film formation step S5, the via plug formation step S6. The manufacturing method of the semiconductor device DEV2 further includes the wiring layer formation step S7, the interlayer dielectric film formation step S8, the via plug formation step S9, the resistive film formation step S10, the cleaning step S11, the interlayer dielectric film formation step S12, the via plug formation step S13, and the wiring layer formation step S14.

In the manufacturing method of the semiconductor device DEV2, during the contact plug formation step S3, after the contact hole CHc and the contact hole CHd are further formed in the interlayer dielectric film ILD1, the contact plug CPc and the contact plug CPd are further formed in the contact hole CHc and the contact hole CHd, respectively. In the manufacturing method of the semiconductor device DEV2, during the wiring layer formation step S4, the wiring WL1c, the wiring WL1d, the wiring WL2c, and the wiring WL2d are further formed.

In the manufacturing method of the semiconductor device DEV2, during the via plug formation step S6, after the via hole VH2c and the via hole VH2d are further formed in the interlayer dielectric film ILD2, the via plug VP2c and the via plug VP2d are formed in the via hole VH2c and the via hole VH2d, respectively. Furthermore, in the manufacturing method of the semiconductor device DEV2, during the via plug formation step S6, after the via hole VH3c and the via hole VH3d are further formed in the interlayer dielectric film ILD3, the via plug VP3c and the via plug VP3d are further formed in the via hole VH3c and the via hole VH3d, respectively.

In the manufacturing method of the semiconductor device DEV2, during the wiring layer formation step S7, the wiring WL3c and the wiring WL3d are further formed. In the manufacturing method of the semiconductor device DEV2, during the via plug formation step S9, after the via hole VH4g and the via hole VH4h are further formed in the first layer ILD4, the via plug VP4ac and the via plug VP4ad are further formed in the via hole VH4g and the via hole VH4h, respectively.

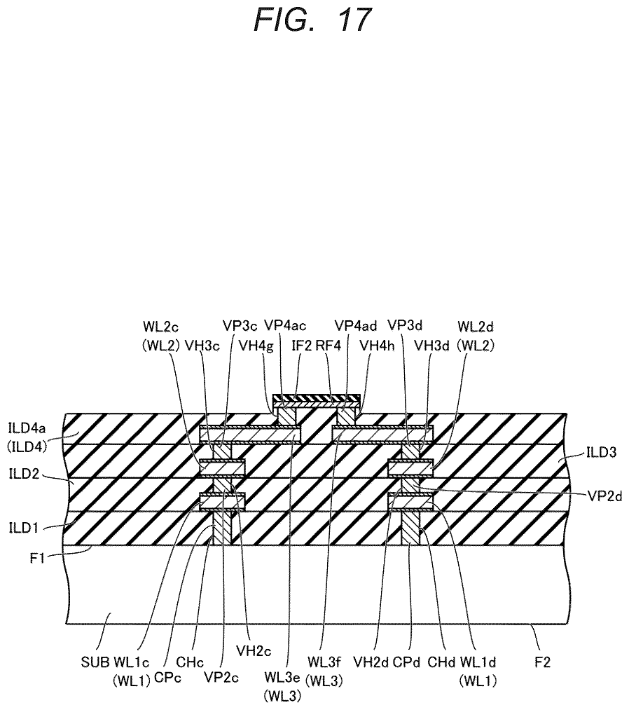

As shown in FIG. 17, in the manufacturing method of the semiconductor device DEV2, during the resistive film formation step S10, the resistive film RF4 and the dielectric film IF2 are further formed. In the manufacturing method of the semiconductor device DEV2, at the completion of the resistive film formation step S10, the side surface of the resistive film RF4 is exposed from between the dielectric film IF2 and the first layer ILD4a, and the resistive film RF4 is electrically connected to the semiconductor substrate SUB. In the cleaning step S11, the upper surface of the first layer ILD4a is cleaned while the resistive film RF4 is electrically connected to the semiconductor substrate SUB. Therefore, in the manufacturing method of the semiconductor device DEV2, during the cleaning step S11, silicon in the resistive film RF4 dissolves, reducing the width of the resistive film RF4.

### Effects of Semiconductor Device DEV3

The effects of the semiconductor device DEV3 are described below.

In the semiconductor device DEV3, during the cleaning step S11, since the resistive film RF4 is electrically connected to the semiconductor substrate SUB, the dissolution of silicon in the resistive film RF4 leads to a reduction in the width of the resistive film RF4. As a result, in the semiconductor device DEV3, by actively utilizing the dissolution of silicon in the resistive film RF4, it becomes possible to form the resistive film RF4 having a width smaller than the resolution limit of photolithography.

As has been specifically described based on embodiments by the inventor of the present invention, it goes without saying that the present invention is not limited to the above-described embodiments and can be variously modified without departing from the gist thereof.

What is claimed is:

1. A semiconductor device comprising:
a semiconductor substrate;
a first interlayer dielectric film formed over the semiconductor substrate;
a first wiring formed on the first interlayer dielectric film;
a second interlayer dielectric film formed on the first interlayer dielectric film, the second interlayer dielectric film comprising:
a first layer covering the first wiring; and
a second layer formed on the first layer;
a first resistive film formed on the first layer and covered by the second layer;
a first via plug formed in the first layer and electrically connecting the first wiring and the first resistive film; and
a second via plug formed in the second interlayer dielectric film and electrically connected to the first wiring,
wherein the first resistive film comprises silicon, and
wherein the first resistive film is electrically connected to the semiconductor substrate through the first wiring, the first via plug, and the second via plug.

2. The semiconductor device according to claim 1, further comprising:
a first dielectric film,
wherein the first dielectric film is formed on the first resistive film,
wherein a side surface of the first resistive film is exposed from between the first layer and the first dielectric film, and
wherein the second layer covers the first dielectric film.

3. The semiconductor device according to claim 1,
wherein the first resistive film is formed of SiCr or SiCrC.

4. The semiconductor device according to claim 1, further comprising:
a second wiring,
wherein the second wiring is formed on the second interlayer dielectric film, and
wherein the second wiring is electrically connected to the second via plug.

5. The semiconductor device according to claim 1 further comprising:
a second resistive film,
wherein the second resistive film is formed on the second interlayer dielectric film,
wherein the second resistive film comprises silicon, and
wherein the second resistive film is electrically connected to the second via plug.

6. The semiconductor device according to claim 5,
wherein the second resistive film is formed of SiCr or SiCrC.

7. The semiconductor device according to claim 1, further comprising:
a third wiring formed on the first interlayer dielectric film and covered by the first layer;
a third resistive film formed on the first layer and covered by the second layer;
a third via plug formed in the first layer and electrically connecting the third wiring and the third resistive film; and
a fourth via plug formed in the first interlayer dielectric film and electrically connected to the third wiring,
wherein the third resistive film comprises silicon.

8. The semiconductor device according to claim 7, further comprising:
a second dielectric film,
wherein the second dielectric film formed on the third resistive film,
wherein a side surface of the third resistive film is exposed from between the first layer and the second dielectric film, and
wherein the second layer covers the second dielectric film.

9. The semiconductor device according to claim 7,
wherein the third resistive film is electrically connected to the semiconductor substrate through the third wiring, the third via plug, and the fourth via plug.

10. The semiconductor device according to claim 7,
wherein the third resistive film is formed of SiCr or SiCrC.

11. The semiconductor device according to claim 7,
wherein a width of the third resistive film is smaller than a width of the first resistive film.

12. A method of manufacturing a semiconductor device, the method comprising:
forming a first interlayer dielectric film on a semiconductor substrate;
forming a first wiring on the first interlayer dielectric film;
forming a first layer of a second interlayer dielectric film on the first interlayer dielectric film to cover the first wiring;
forming a first via plug in the first layer to be electrically connected to the first wiring;
forming a first resistive film comprising silicon on the first layer to be electrically connected to the first via plug;
forming a second layer of the second interlayer dielectric film on the first layer to cover the first resistive film; and
after forming the first resistive film, cleaning an upper surface of the first layer,
wherein in cleaning the upper surface of the first layer, the upper surface of the first layer is cleaned in a state where the first resistive film is not electrically connected to the semiconductor substrate.

13. The method according to claim 12, further comprising:
after cleaning the upper surface of the first layer, forming the second layer of the second interlayer dielectric film on the first layer to cover the first resistive film; and
forming a second via plug in the second interlayer dielectric film to be electrically connected to the first wiring.

14. The method according to claim 13, further comprising:
after forming the second via plug, forming a second wiring on the second interlayer dielectric film to be electrically connected to the second via plug,
wherein the first resistive film is electrically connected to the semiconductor substrate through the first wiring, the second wiring, the first via plug, and the second via plug.

15. The method according to claim 13,
wherein the first resistive film is formed of SiCr or SiCrC.

16. The method according to claim 13, further comprising:
after forming the second via plug, forming a second resistive film on the second interlayer dielectric film to be electrically connected to the second via plug,
wherein the second resistive film comprises silicon, and
wherein the first resistive film is electrically connected to the semiconductor substrate through the first wiring, the second resistive film, the first via plug, and the second via plug.

17. The method according to claim 12, further comprising:
forming a fourth via plug in the first interlayer dielectric film;
forming a third wiring on the first interlayer dielectric film to be connected to the fourth via plug;
forming a third via plug first layer to be electrically connected to the third wiring; and
forming a third resistive film on the first layer,
wherein the third resistive film comprises silicon, and
wherein in cleaning the upper surface of the first layer, the upper surface of the first layer is cleaned in a state where the third resistive film is electrically connected to the semiconductor substrate.

18. The method according to claim 17,
wherein after cleaning the upper surface of the first layer, a width of the third resistive film is smaller than a width of the first resistive film.
